(19) United States
(12) Patent Application Publication
(10) Pub. No.: US 2006/0115683 A1
(43) Pub. Date: Jun. 1, 2006

(54) Coated inserts for dry milling

(75) Inventor: Ingemar Hessman, Sandviken (SE)

Correspondence Address: DRINKER BIDDLE & REATH (DC), 1500 K STREET, N.W., SUITE 1100, WASHINGTON, DC, 20005-1209, US

(73) Assignee: SANDVIK INTELLECTUAL PROPERTY AB

(21) Appl. No.: 11/261,908

(22) Filed: Oct. 31, 2005

(30) Foreign Application Priority Data
Nov. 7, 2004 (SE) 0402709-0

(51) Int. Cl. B32B 9/00; B32B 19/00; C23C 16/00; B05D 3/00

(52) U.S. Cl. 428/698; 428/701; 428/702; 427/331; 427/248.1

(57) ABSTRACT

Coated milling inserts particularly useful for milling of grey cast iron with or without cast skin under dry conditions at generally high cutting speeds and milling of nodular cast iron and compacted graphite iron with or without cast skin under dry conditions at rather high cutting speeds are disclosed.

The inserts are characterised by a WC—Co cemented carbide with a low content of cubic carbides and a highly W-alloyed binder phase and a coating including an inner layer of TiCₓN_{y} with columnar grains followed by a wet blasted layer of α-Al₂O₃.

### BACKGROUND OF THE INVENTION

The present invention relates to coated cemented carbide cutting tool inserts particularly useful for rough milling of highly alloyed grey cast iron, nodular cast iron and compacted graphite iron with or without cast skin under dry conditions, preferably at rather high cutting speeds.

U.S. Pat No. 6,638,609 discloses coated milling inserts particularly useful for milling of grey cast iron with or without cast skin under wet conditions at low and moderate cutting speeds and milling of nodular cast iron and compacted graphite iron with or without cast skin under wet conditions at moderate cutting speeds. The inserts are characterized by a WC—Co cemented carbide with a low content of cubic carbides and a highly W-alloyed binder phase and a coating including an inner layer of TiCₓN_{y} with columnar grains followed by a layer of κ-Al₂O₃ and a top layer of TiN.

### OBJECTS AND SUMMARY OF THE INVENTION

It is an object of the present invention to provide coated cemented carbide cutting tool inserts, particularly useful for rough milling under dry conditions of highly alloyed grey cast iron, nodular cast iron and compacted graphite iron under dry conditions, preferably at rather high cutting speeds.

In one aspect of the invention there is provided a cutting tool insert a cemented carbide body and a coating wherein said cemented carbide body comprises WC with an average grain size of from about 1.5 to about 2.5 μm, of from about 7.3 to about 7.9 wt-% Co and from about 1.0 to about 1.8 wt % cubic carbides of metals Ta and Nb and a highly W-alloyed binder phase with a CW-ratio of 0.86-0.94 with less than about 3 vol-% eta-phase and said coating comprising:

a first, innermost layer of TiCₓN_{y}O_{z} with x+y+z=1, y>x and z less than to about 0.2 with equiaxed grains with size less than about 0.5 μm and a total thickness of from about 0.1 to about 1.5 μm,

a layer of TiCₓN_{y} with x+y=1, x greater than about 0.3 and y greater than about 0.3 with a thickness of from about 4.5 to about 9.5 μm with columnar grains with an average diameter of less than about 5 μm,

a layer of a smooth, fine-grained, from about 0.5 to about 2 μm average grain size α-Al₂O₃ with a thickness of from about 4.5 to about 9.5 μm.

In another aspect of the invention there is provided a method of making a milling insert comprising a cemented carbide body and a coating wherein the WC—Co-based cemented carbide body comprises WC, to from about 7.3 to about 7.9 wt-% Co and from about 1.0 to about 1.8 wt-% cubic carbides of Ta and Nb and a highly W-alloyed binder phase with a CW-ratio of 0.86-0.94, the method comprising the steps of:

depositing by a CVD-method a first, innermost layer of TiCₓN_{y}O_{z} with x+y+z=1, y>x and z less than about 0.2 having an equiaxed grain structure with a size less than about 0.5 μm and a total thickness of from about 0.1 to about 1.5 μm,

depositing by a MTCVD-technique a layer of TiCₓN_{y} with x+y=1, x greater than about 0.3 and y greater than about 0.3 with a thickness of from about 4.5 to about 9.5 μm having a columnar grain structure with an average diameter of less than about 5 μm, wherein the MTCVD-technique uses acetonitrile as a source of carbon and nitrogen for forming a layer in a temperature range of from about 700 to about 900° C.,

depositing a layer of α-Al₂O₃ with a thickness of from about 4.5 to about 9.5 μm using known CVD-methods and

dry blasting said layer with alumina grit in order to obtain smooth surface finish.

In still another aspect of the invention, there is provided the use of the cutting tool insert described above for wet milling using fluid coolant of cast irons such as grey cast iron, compacted graphite iron and nodular iron at a cutting speed of from about 100 to about 300 m/min and a feed of from about 0.15 to about 0.35 mm/tooth.

### DETAILED DESCRIPTION OF THE INVENTION

It has now surprisingly been found that cutting tool inserts showing improved properties with respect to the different wear types prevailing at the above mentioned cutting operations can be obtained with cutting tool inserts comprising a cemented carbide body with a relatively high W-alloyed binder phase and with a well balanced chemical composition and grain size of the WC, a columnar TiCₓN_{y}-layer and a wet blasted α-Al₂O₃-layer.

According to the present invention coated cutting tool inserts are provided of a cemented carbide body with a composition of from about 7.3 to about 7.9 wt% Co, preferably about 7.6 wt% Co, of from about 1.0 to about 1.8 wt % cubic carbides, preferably of from about 1.4 to about 1.7 wt % cubic carbides of the metals Ta and Nb and balance WC. The average grain size of the WC is in the range of about from 1.5 to about 2.5 μm, preferably about 1.8 μm.

The cobalt binder phase is rather highly alloyed with W. The content of W in the binder phase can be expressed as the CW-ratio=Mₛ/(wt % Co.0.0161), where Mₛ is the saturation magnetization of the cemented carbide body in kA/m and wt % Co is the weight percentage of Co in the cemented carbide. The CW-value is a function of the W content in the Co binder phase. A high CW-value corresponds to a low W-content in the binder phase.

It has now been found according to the present invention that improved cutting performance is achieved if the cemented carbide body has a CW-ratio of 0.86-0.94. The cemented carbide may contain small amounts, less than about 3 vol %, of η-phase (M₆C), without any detrimental effect.

The uncoated cutting edge has a radius of 35-60 μm.

The coating comprises:

a first (innermost) layer of TiCₓN_{y}O_{z} with x+y+z=1, y>x and z less than 0.2, preferably y greater than about 0.8 and z=0, with equiaxed grains with size less than 0.5 μm and a total thickness less than 1.5 μm, preferably greater than about 0.1 μm,

a layer of TiCₓN_{y} with x+y=1, x greater than about 0.3 and y greater than about 0.3, preferably x greater than or equal to about 0.5, with a thickness of from about 4.5 to about 9.5 μm, preferably from about 5 to about 8 μm, with columnar grains and with an average diameter of less than about 5 μm, preferably from about 0.1 to about 2 μm,

a layer of a smooth, fine-grained (average grain size about from about 0.5 to about 2 μm) Al₂O₃ consisting essentially of the α-phase. However, the layer may contain small amounts (less than about 5 vol-%) of other phases such as θ- or κ-phase as determined by XRD-measurement. The Al₂O₃-layer has a thickness of from about 4.5 to about 9.5 μm, preferably from about 5 to about 8 μm with a surface roughness of preferably Rₘₐₓ≦0.4 μm over a length of 10 μm.

The present invention also relates to a method of making coated cutting tool inserts of a coated cemented carbide body with a composition of from about 7.3 to about 7.9 wt% Co, preferably about 7.6 wt% Co, from about 1.0 to about 1.8 wt%, preferably from about 1.4 to about 1.7 wt % cubic carbides of the metals Ta and Nb and balance WC. The average grain size of the WC is in the range of from about 1.5 to about 2.5 μm, preferably about 1.8 μm.

The cobalt binder phase is rather highly alloyed with W to a CW-ratio of 0.86-0.94 defined as above. The cemented carbide may contain small amounts, less than about 3 vol %, of η-phase (M₆C), without any detrimental effect.

The inserts are dry blasted to from about 35 to about 60 μm edge honing and after that a coating is deposited comprising:

a first (innermost) layer of TiCₓN_{y}O_{z} with x+y+z=1, y>x and z less than about 0.2, preferably y greater than about 0.8 and z=0, with equiaxed grains with size less than about 0.5 μm and a total thickness less than about 1.5 μm, preferably greater than about 0.1 μm, using known CVD-methods,

a layer of TiCₓN_{y} with x+y=1, x greater than about 0.3 and y greater than about 0.3, preferably x greater than or equal to about 0.5, with a thickness of from about 4.5 to about 9.5 μm, preferably from about 5 to about 8 μm, with columnar grains and with an average diameter of less than about 5 μm, preferably from about 0.1 to about 2 μm using preferably MTCVD-technique (using acetonitrile as the carbon and nitrogen source for forming the layer in the temperature range of from about 700 to about 900° C.). The exact conditions, however, depend to a certain extent on the design of the equipment used,

a layer of a smooth, fine-grained (average grain size of from about 0.5 to about 2 μm) Al₂O₃ consisting essentially of the α-phase using known CVD-methods. However, the layer may contain small amounts (less than about 5 vol-%) of other phases such as θ- or κ-phase as determined by XRD-measurement. The Al₂O₃-layer has a thickness of from about 4.5 to about 9.5 μm, preferably of from about 5 to about 8 μm.

Finally the inserts are dry blasted with alumina grit in order to obtain smooth surface finish, preferably a surface roughness Rₘₐₓ≦0.4 μm over a length of 10 μm.

The invention also relates to the use of cutting tool inserts according to above for rough milling under dry conditions of highly alloyed grey cast iron, compacted graphite iron and nodular iron with or without cast skin, at a cutting speed of from about 100 to about 300 m/min and a feed of from about 0.15 to about 0.35 mm/tooth depending on cutting speed and insert geometry.

The invention is additionally illustrated in connection with the following examples, which are to be considered as illustrative of the present invention. It should be understood, however, that the invention is not limited to the specific details of the examples.

### EXAMPLE 1

A. Cemented carbide milling inserts in accordance with the invention with the composition 7.6 wt-% Co, 1.25 wt-% TaC, 0.30 wt-% NbC and balance WC with average grain size of 1.8 μm, with a binder phase alloyed with W corresponding to a CW-ratio of 0.87 were coated with a 0.5 μm equiaxed TiC_{0.05}N_{0.95}-layer (with a high nitrogen content corresponding to an estimated C/N-ratio of 0.05) followed by a 11 μm thick TiC_{0.54}N_{0.46}-layer, with columnar grains by using MTCVD-technique (temperature 850-885° C. and CH₃CN as the carbon/nitrogen source). In subsequent steps during the same coating cycle, a 4 μm thick layer of α-Al₂O₃ was deposited using a temperature 970° C. and a concentration of H₂S dopant of 0.4 % as disclosed in EP-A-523 021.

The inserts were dry blasted with alumina grit in order to obtain a smooth surface finish.

### EXAMPLE 2

Inserts according to the present invention were tested in a face milling of a cylinder block in a highly alloyed grey cast iron

Tool: Sandvik Coromant R260.31-250

Number of inserts: 40 PCs

Criterion: Surface finish and work piece frittering.

Reference: TNEF 1204AN-CA in grade Sandvik Coromant GC3020

A: Competitor grade

B: Competitor grade

Cutting data

Cutting speed: Vc=120 m/min

Feed per tooth: Fz=0.2 mm per tooth

Depth of cut: Ap=4 mm

Dry conditions

Tool life reference GC3020 ( prior art) 1000 engine blocks in production.

Tool life of invention 2073 cylinder heads. Average of 5 tests.

Increase of tool life 107% with improved surface finish and productivity.

Tool life competitor A 1187 PCs.

Tool life competitor B 1205 PCs.

### EXAMPLE 3

Inserts according to the present invention were tested in a face milling of cylinder heads in highly alloyed grey cast iron

Tool: Sandvik Coromant R260.31-315

Number of inserts: 50 PCs

Criteria: Surface finish and work piece frittering.

Reference TNEF 1204AN-WL in grade Sandvik Coromant GC3040

Cutting data

Cutting speed: Vc=283 m/min

Feed per tooth: Fz=0.27 mm per tooth

Depth of cut: Ap=3-5 mm

Dry conditions

Tool life reference GC3040 75 cylinder heads in standard production.

Tool life of invention 231 cylinder heads. Average of 5 tests

Increase of tool life 208% with improved surface finish.

Although the present invention has been described in connection with preferred embodiments thereof, it will be appreciated by those skilled in the art that additions, deletions, modifications, and substitutions not specifically described may be made without department from the spirit and scope of the invention as defined in the appended claims.

1. A cutting tool insert comprising a cemented carbide body and a coating wherein said cemented carbide body comprises WC with an average grain size of from about 1.5 to about 2.5 μm, of from about 7.3 to about 7.9 wt-% Co and from about 1.0 to about 1.8 wt% cubic carbides of metals Ta and Nb and a highly W-alloyed binder phase with a CW-ratio of 0.86-0.94 with less than about 3 vol-% eta-phase and said coating comprising:
a first, innermost layer of TiCₓN_{y}O_{z} with x+y+z=1, y>x and z less than about 0.2 with equiaxed grains with size less than about 0.5 μm and a total thickness of from about 0.1 to about 1.5 μm,
a layer of TiCₓN_{y} with x+y=1, x greater than about 0.3 and y greater than about 0.3 with a thickness of from about 4.5 to about 9.5 μm with columnar grains with an average diameter of less than about 5 μm,
a layer of a smooth, fine-grained, from about 0.5 to about 2 μm average grain size α-Al₂O₃ with a thickness of from about 4.5 to about 9.5 μm.

2. The cutting insert of claim 1 wherein the cemented carbide contains to from about 1.4 to about 1.7 wt-% carbides of Ta and Nb.

3. The cutting insert of claim 1 wherein said insert has an uncoated cutting edge having a radius of 35-60 μm.

4. The cutting tool of claim 1 wherein in said first, innermhost layer, y is greater than about 0.8 and z=0, in said TiCₓN_{y} layer, x is greater than or equal to about 0.5 and said layer of α-Al₂O₃ has a surface roughness or Rₘₐₓ less than or equal to about 0.4 μm over a length of 10 μm.

5. A method of making a milling insert comprising a cemented carbide body and a coating wherein the WC—Co-based cemented carbide body comprises WC, to from about 7.3 to about 7.9 wt-% Co and to from about 1.0 to about 1.8 wt-% cubic carbides of Ta and Nb and a highly W-alloyed binder phase with a CW-ratio of 0.86-0.94, the method comprising the steps of:
depositing by a CVD-method a first, innermost layer of TiCₓN_{y}O_{z} with x+y+z=1, y>x and z less than about 0.2 having an equiaxed grain structure with a size less than about 0.5 μm and a total thickness of from about 0.1 to about 1.5 μm,
depositing by a MTCVD-technique a layer of TiCₓN_{y} with x+y=1, x greater than about 0.3 and y greater than about 0.3 with a thickness of from about 4.5 to about 9.5 μm having a columnar grain structure with an average diameter of less than about 5 μm, wherein the MTCVD-technique uses acetonitrile as a source of carbon and nitrogen for forming a layer in a temperature range of from about 700 to about 900° C.,
depositing a layer of α-Al₂O₃ with a thickness of from about 4.5 to about 9.5 μm using known CVD-methods and
dry blasting said layer with alumina grit in order to obtain a smooth surface finish.

6. The method of claim 5 wherein said cemented carbide body contains to from about 1.4 to about 1.7 wt-% carbides of Ta and Nb.

7. The method of claim 5 comprising dry blasting the inserts to from about 35 to about 60 μm edge honing before coating.

8. The method of claim 5 where said dry blasting is performed to obtain a surface roughness or Rₘₐₓ less than or equal to about 0.4 μm over a length of 10 μm.

9. The use of a cutting tool insert of claim 1 for wet milling using fluid coolant of cast irons such as grey cast iron, compacted graphite iron and nodular iron at a cutting speed of from about 100 to about 300 m/min and a feed of from about 0.15 to about 0.35 mm/tooth.
